(19) United States
(12) Patent Application Publication
(10) Pub. No.: US 2026/0037208 A1
(43) Pub. Date: Feb. 5, 2026

(54) AUDIO PROCESSING CIRCUIT

(71) Applicant: Sigmastar Technology Ltd., Xiamen (CN)

(72) Inventors: Chen Hui Luo, Xiamen (CN); Chun Bin Li, Xiamen (CN); Zhun Chen, Xiamen (CN); Jian Feng Xue, Xiamen (CN)

(21) Appl. No.: 19/272,550

(22) Filed: Jul. 17, 2025

(30) Foreign Application Priority Data
Jul. 31, 2024 (CN) 202411042872.4

(51) Int. Cl. G06F 3/16; H03K 3/037; H03M 1/12

(52) U.S. Cl. CPC G06F 3/16; H03K 3/037; H03M 1/12

(57) ABSTRACT

An audio processing circuit includes a clock generation circuit, a first analog-to-digital converter (ADC), a second ADC, a first data alignment circuit, and a second data alignment circuit. The clock generation circuit is configured to generate a first sampling clock and a second sampling clock. The first ADC is configured to convert an input signal into a first digital code according to the first sampling clock. The second ADC is configured to convert the input signal into a second digital code according to the second sampling clock. The first data alignment circuit is configured to receive the first digital code and generate a third digital code. The second data alignment circuit is configured to receive the second digital code and generate a fourth digital code.

This application claims the benefit of China application Serial No. CN 202411042872.4, filed on Jul. 31, 2024, the subject matter of which is incorporated herein by reference.

### BACKGROUND OF THE INVENTION

### 1. Field of the Invention

The present invention generally relates to an audio processing circuit, and more particularly, to a multichannel audio processing circuit.

### 2. Description of Related Art

FIG. 1 shows a conventional audio processing circuit. The audio processing circuit 110 includes an analog-to-digital converter (ADC) 112, an ADC 114, and a clock generation circuit 116. The audio processing circuit 110 includes multiple channels, and the ADC 112 and the ADC 114 correspond to two of the channels. The audio between the multiple channels must be synchronized. The low-dropout regulator 102 provides the power supply voltage VDD1 required by the ADC 112, while the low-dropout regulator 104 provides the power supply voltage VDD2 required by the ADC 114. The clock generation circuit 116 generates the sampling clock CLK. The ADC 112 converts the input signal Vin into the digital code D1 according to the sampling clock CLK. The ADC 114 converts the input signal Vin into the digital code D2 according to the sampling clock CLK. The fact that the ADC 112 and the ADC 114 each require a low-dropout regulator results in an increase in the overall circuit area and a rise in cost.

### SUMMARY OF THE INVENTION

In view of the issues of the prior art, an object of the present invention is to provide an audio processing circuit, so as to make an improvement to the prior art.

According to one aspect of the present invention, an audio processing circuit is provided. The audio processing circuit includes: a clock generation circuit configured to generate a sampling clock; a chopping clock generation circuit configured to generate a chopping clock; a first analog-to-digital converter (ADC), coupled to the clock generation circuit and the chopping clock generation circuit and configured to convert an input signal into a first digital code according to the sampling clock, and to perform a first chopping operation according to the chopping clock; and a second ADC, coupled to the clock generation circuit and the chopping clock generation circuit and configured to convert the input signal into a second digital code according to the sampling clock, and to perform a second chopping operation according to the chopping clock. The first ADC and the second ADC perform the first chopping operation and the second chopping operation substantially simultaneously at a first time point, and the first ADC and the second ADC perform a sampling operation substantially simultaneously at a second time point after the first time point. The time difference between the second time point and the first time point is greater than one-fourth of a period of the sampling clock.

According to another aspect of the present invention, an audio processing circuit is provided. The audio processing circuit includes: a clock generation circuit configured to generate a first sampling clock and a second sampling clock; a first analog-to-digital converter (ADC), coupled to the clock generation circuit and configured to convert an input signal into a first digital code according to the first sampling clock; a second ADC, coupled to the clock generation circuit and configured to convert the input signal into a second digital code according to the second sampling clock; a first data alignment circuit, coupled to the first ADC and configured to receive the first digital code and generate a third digital code; and a second data alignment circuit, coupled to the second ADC and configured to receive the second digital code and generate a fourth digital code.

The technical means embodied in the embodiments of the present invention can solve at least one of the problems of the prior art. Therefore, compared to the prior art, the present invention can reduce the increase in circuit area, lower costs, and enhance the stability of the circuit.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 shows a conventional audio processing circuit.

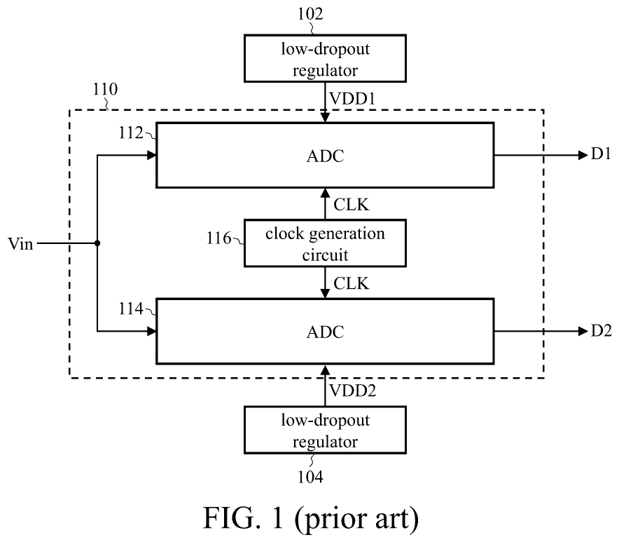

FIG. 2 is a functional block diagram of the audio processing circuit according to an embodiment of the present invention.

FIG. 3 shows the waveforms of the sampling clock, the chopping clock, and the power supply voltage according to an embodiment of the present invention.

FIG. 4 shows the waveforms of the sampling clock, the chopping clock, and the power supply voltage according to another embodiment of the present invention.

FIG. 5 is the functional block diagram of the audio processing circuit according to another embodiment of the present invention.

FIG. 6 shows the waveforms of the sampling clock and the power supply voltage from FIG. 5 according to an embodiment.

FIG. 7 is the circuit diagram of the clock generation circuit according to an embodiment of the present invention.

FIG. 8 is a functional block diagram of the data alignment circuit according to an embodiment of the present invention.

FIG. 9 is a functional block diagram of the audio processing circuit according to another embodiment of the present invention.

FIG. 10 shows the waveforms of the sampling clock, the chopping clock, and the power supply voltage from FIG. 9 according to an embodiment.

FIG. 11 shows the waveforms of the sampling clock, the chopping clock, and the power supply voltage from FIG. 9 according to another embodiment.

FIG. 12 is a functional block diagram of the data alignment circuit according to another embodiment of the present invention.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes an audio processing circuit. On account of that some or all elements of the audio processing circuit could be known, the detail of such elements is omitted provided that such detail has little to do with the features of this disclosure, and that this omission nowhere dissatisfies the specification and enablement requirements. A person having ordinary skill in the art can choose components or steps equivalent to those described in this specification to carry out the present invention, which means that the scope of this invention is not limited to the embodiments in the specification.

In the following description, signals are active-high, which means that signals are active at high levels and inactive at low levels, and that asserting/de-asserting a signal means setting the signal high/low. This is for the purpose of explanation, not for limiting the scope of the invention. In other words, in an alternative implementation, signals can be active-low, which means that signals are active at low levels and inactive at high levels, and that asserting/de-asserting a signal means setting the signal low/high. A level transition or a logic level transition means that a signal changes from an asserted (active) state to a de-asserted (inactive) state, or from a de-asserted (inactive) state to an asserted (active) state.

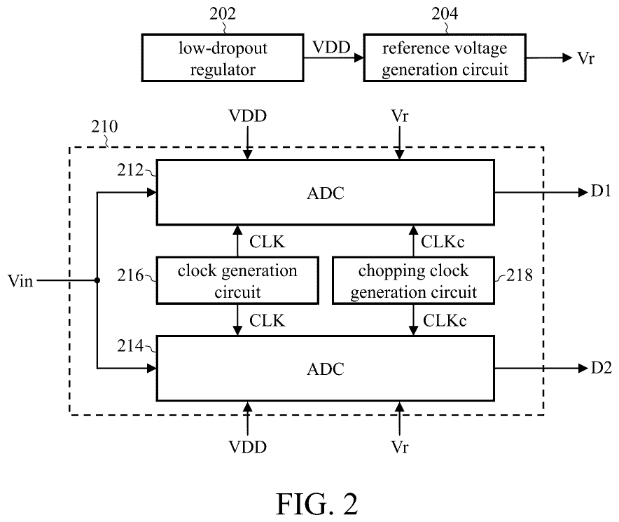

Reference is made to FIG. 2, which is a functional block diagram of the audio processing circuit according to an embodiment of the present invention. The audio processing circuit 210 includes an ADC 212, an ADC 214, a clock generation circuit 216, and a chopping clock generation circuit 218 all of which are coupled to each other. The audio processing circuit 210 includes multiple channels, and the ADC 212 and the ADC 214 correspond to two of the channels. The ADC 212 and the ADC 214 convert the input signal Vin (e.g., an audio signal) into a digital code D1 and a digital code D2, respectively, according to the sampling clock CLK. The ADC 212 and the ADC 214 share a low-dropout regulator 202, a reference voltage generation circuit 204, the clock generation circuit 216, and the chopping clock generation circuit 218. The low-dropout regulator 202 generates the power supply voltage VDD required for the operation of the ADC 212 and the ADC 214. The reference voltage generation circuit 204 generates the reference voltage Vr based on the power supply voltage VDD. The ADC 212 and the ADC 214 use the reference voltage Vr to perform chopping operations. The clock generation circuit 216 generates the sampling clock CLK. The chopping clock generation circuit 218 generates the chopping clock CLKc. In some embodiments, the ADC 212 and the ADC 214 are sigma-delta modulators (SDMs), and the integrator and the digital-to-analog converter (DAC) in the SDM perform the chopping operations according to the reference voltage Vr and the chopping clock CLKc to improve the quality of the signal. The chopping operation is well known to people having ordinary skill in the art, so further elaboration is omitted for brevity.

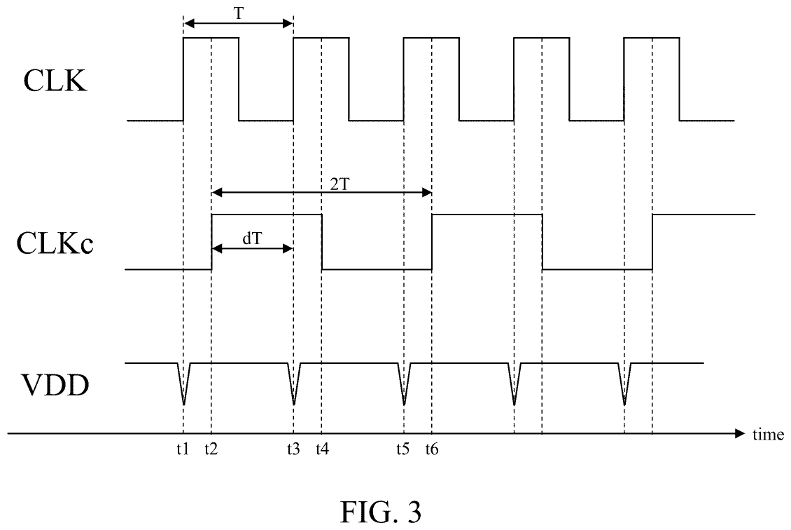

Reference is made to FIG. 3, which shows the waveforms of the sampling clock CLK, the chopping clock CLKc, and the power supply voltage VDD according to an embodiment of the present invention. The period of the sampling clock CLK is T, and the period of the chopping clock CLKc is 2T. The ADC 212 and the ADC 214 sample at the rising edges of the sampling clock CLK (e.g., time point t1, time point t3), and perform chopping operations at the rising edges of the chopping clock CLKc (e.g., time point t2, time point t6). Due to the fact that the ADC 212 and the ADC 214 share the low-dropout regulator 202 and perform sampling operations at substantially the same time at the rising edges of the sampling clock CLK, the power supply voltage VDD experiences a relatively large drop.

In the present invention, the time difference dT between the rising edge of the chopping clock CLKc and the rising edge of the sampling clock CLK is greater than one-fourth of the period T of the sampling clock CLK (i.e., dT>T/4). That is to say, for the ADC 212 and the ADC 214, the time difference dT between the chopping operation and the sampling operation is greater than one-fourth of the period T of the sampling clock CLK. The advantage of such a design is that the ADC 212 and the ADC 214 have DACs with more ample establishment time (greater than T/4), which enhances the stability of the circuit. Preferably, the time difference dT is greater than T/2. In some embodiments (as shown in FIG. 3), the time difference dT is substantially equal to 3T/4.

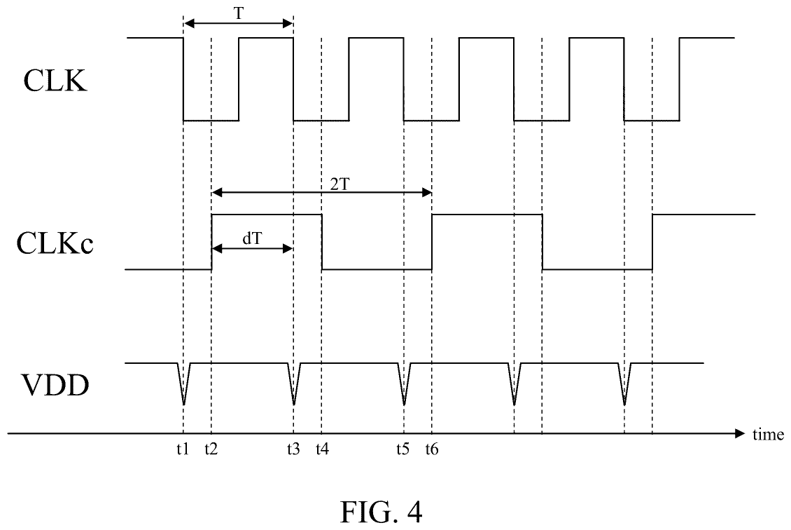

Reference is made to FIG. 4, which shows the waveforms of the sampling clock CLK, the chopping clock CLKc, and the power supply voltage VDD according to another embodiment of the present invention. In this embodiment, the ADC 212 and the ADC 214 sample at the falling edges of the sampling clock CLK and perform chopping operations at the rising edges of the chopping clock CLKc. Similarly, in this embodiment, the establishment time of the DACs in the ADC 212 and the ADC 214 can be greater than T/4.

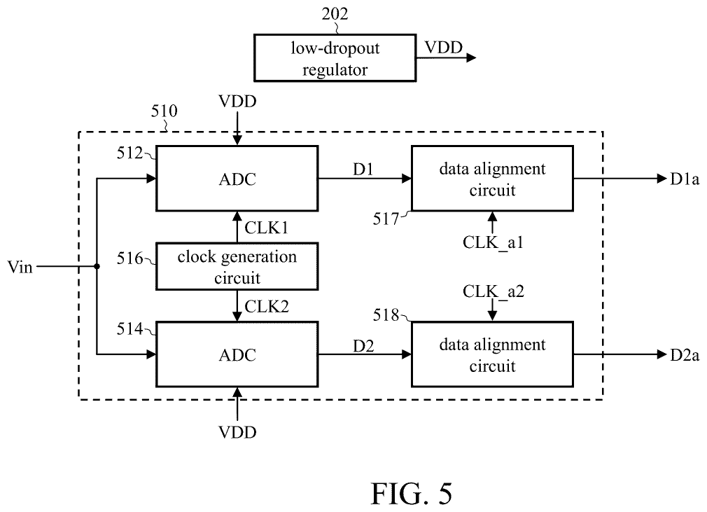

Reference is made to FIG. 5, which is a functional block diagram of an audio processing circuit according to another embodiment of the present invention. The audio processing circuit 510 includes an ADC 512, an ADC 514, a clock generation circuit 516, a data alignment circuit 517, and a data alignment circuit 518 all of which are coupled to each other. The ADC 512 and the ADC 514 share the low-dropout regulator 202 and the clock generation circuit 516. The low-dropout regulator 202 generates the power supply voltage VDD required for the operation of the ADC 512 and the ADC 514. The clock generation circuit 516 generates the sampling clock CLK1 and the sampling clock CLK2. The ADC 512 converts the input signal Vin into the digital code D1 according to the sampling clock CLK1. The ADC 514 converts the input signal Vin into the digital code D2 according to the sampling clock CLK2. The data alignment circuit 517 receives the digital code DI and outputs the digital code D1a according to the clock CLK_a1. The data alignment circuit 518 receives the digital code D2 and outputs the digital code D2a according to the clock CLK_a2.

The ADC 512 and the ADC 514 may be any type of ADC.

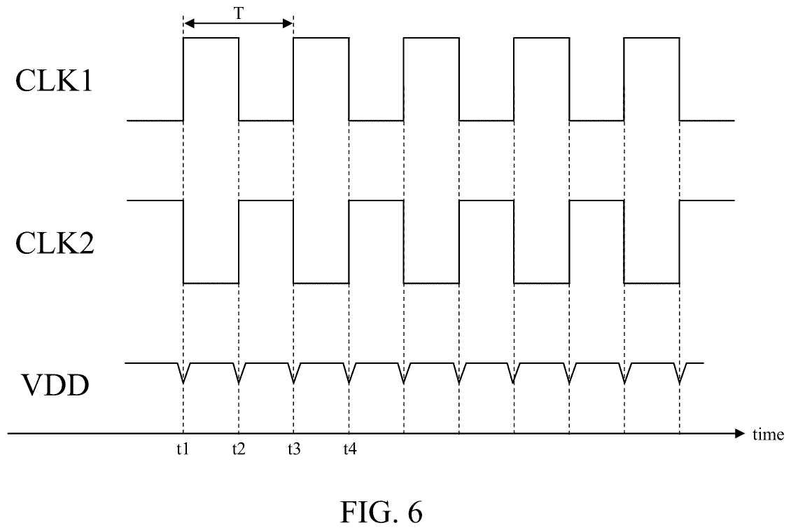

Reference is made to FIG. 6, which shows the waveforms of the sampling clock CLK1, the sampling clock CLK2, and the power supply voltage VDD from FIG. 5 according to an embodiment. The sampling clock CLK1 and the sampling clock CLK2 have the same period T, but the phase difference between the sampling clock CLK1 and the sampling clock CLK2 is substantially 180 degrees.

The ADC 512 performs sampling operations at the rising edges of the sampling clock CLK1 (e.g., time point t1, time point t3, . . . ), and the ADC 514 performs sampling operations at the rising edges of the sampling clock CLK2 (e.g., time point t2, time point t4, . . . ). That is to say, the sampling operation of the ADC 512 and the sampling operation of the ADC 514 are not simultaneous, but are shifted by substantially T/2. The advantage of this design is that the voltage drop of the power supply voltage VDD is only about half of that in FIG. 3 (corresponding to two ADCs performing sampling operations at substantially the same time), which can improve the stability of the circuit.

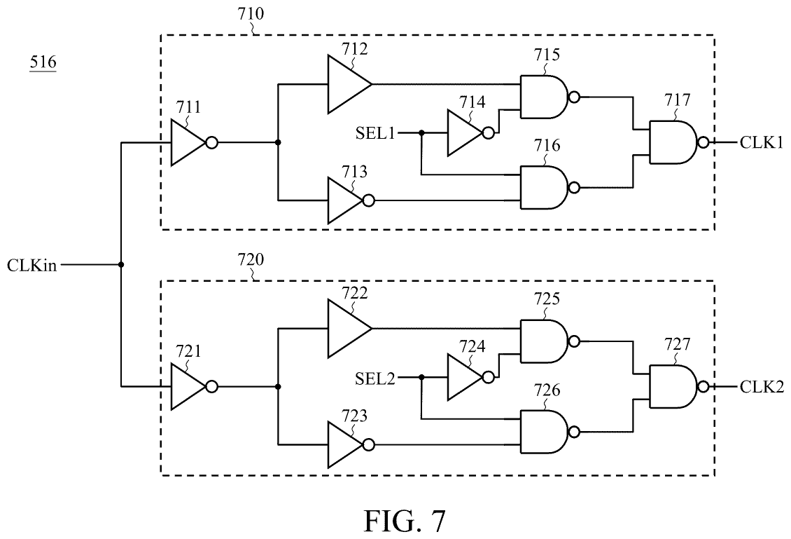

Reference is made to FIG. 7, which is a circuit diagram of the clock generation circuit according to an embodiment of the present invention. The clock generation circuit 516 includes a logic circuit 710 and a logic circuit 720. The logic circuit 710 and the logic circuit 720 respectively generate the sampling clock CLK1 and the sampling clock CLK2 according to the input clock CLKin. The logic circuit 710 (720) includes an inverter 711 (721), a buffer circuit 712 (722), an inverter 713 (723), an inverter 714 (724), a NAND gate 715 (725), a NAND gate 716 (726), and a NAND gate 717 (727) all of which are coupled to each other. As the operating principles of these components are well known to people having ordinary skill in the art, further elaboration is omitted for brevity.

The inverter 714 and the inverter 724 respectively receive the selection signal SEL1 and the selection signal SEL2. When the selection signal SEL1 and the selection signal SEL2 are at the same level, the phase difference between the sampling clock CLK1 and the sampling clock CLK2 is substantially 0 degrees (i.e., in-phase). When the selection signal SEL1 and the selection signal SEL2 are at different levels, the phase difference between the sampling clock CLK1 and the sampling clock CLK2 is substantially 180 degrees.

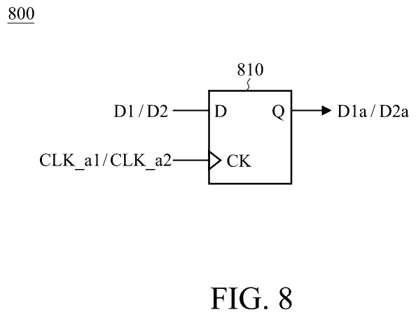

Reference is made to FIG. 8, which is a functional block diagram of the data alignment circuit according to an embodiment of the present invention. The data alignment circuit 800 includes a D flip-flop 810. The data alignment circuit 517 and the data alignment circuit 518 can be implemented by the data alignment circuit 800. The data input terminal D of the D flip-flop 810 receives the digital code DI or the digital code D2. The clock input terminal CK of the D flip-flop 810 receives the clock CLK al or the clock CLK_a2. The output terminal Q of the D flip-flop 810 outputs the digital code D1a or the digital code D2a.

For the data alignment circuit 517, the clock CLK_a1 is a low-level (e.g., logic 0) signal (i.e., a direct current (DC) signal). For the data alignment circuit 518, the clock CLK_a2 is substantially identical to the sampling clock CLK1. In this way, the digital code D1a aligns with the digital code D2a, which is equivalent to the audio processing circuit 510 simultaneously outputting the digital code D1 and the digital code D2, meaning audio synchronization between the two channels.

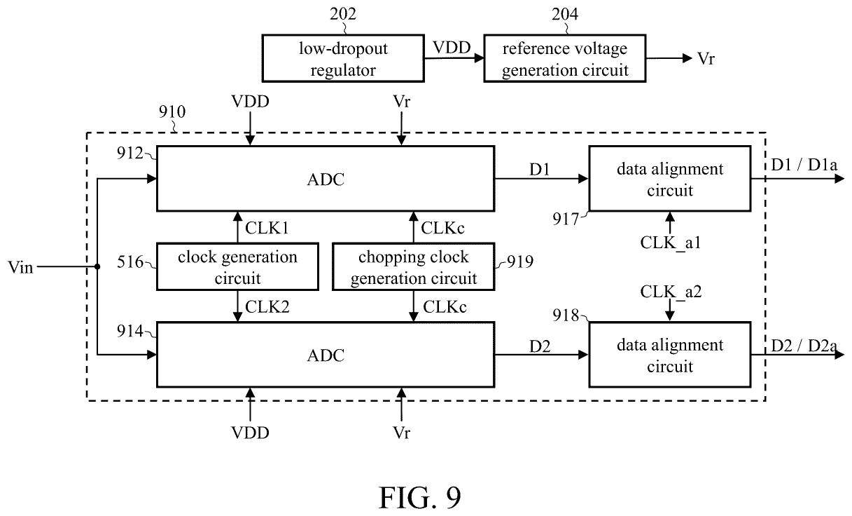

Reference is made to FIG. 9, which is a functional block diagram of the audio processing circuit according to another embodiment of the present invention. The audio processing circuit 910 is similar to the audio processing circuit 510, except that the audio processing circuit 910 further includes a chopping clock generation circuit 919. The function of the chopping clock generation circuit 919 is substantially the same as the function of the chopping clock generation circuit 218, and the chopping clock generation circuit 919 is configured to generate the chopping clock CLKc required by the ADC 912 and the ADC 914. In the embodiment of FIG. 9, the ADC 912 and the ADC 914 are SDMs. In addition to converting the input signal Vin into the digital code D1 or the digital code D2 according to the sampling clock CLK1 or the sampling clock CLK2, the ADC 912 and the ADC 914 also perform chopping operations based on the reference voltage Vr and the chopping clock CLKc. In some embodiments, the data alignment circuit 917 and the data alignment circuit 918 can be implemented by the data alignment circuit 800.

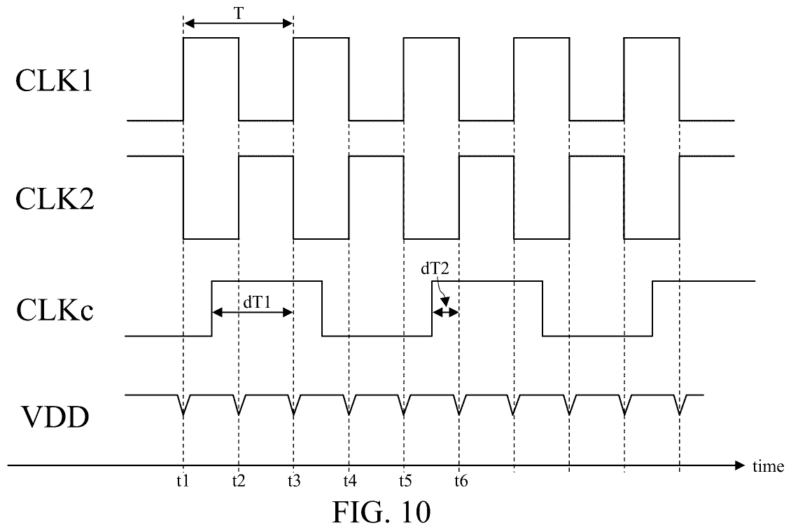

Reference is made to FIG. 10, which shows the waveforms of the sampling clock CLK1, the sampling clock CLK2, the chopping clock CLKc, and the power supply voltage VDD from FIG. 9 according to an embodiment. The phase difference between the sampling clock CLK1 and the sampling clock CLK2 is substantially 180 degrees. There is a time difference dT1 between the rising edge of the chopping clock CLKc and the rising edge of the sampling clock CLK1. There is a time difference dT2 between the rising edge of the chopping clock CLKc and the rising edge of the sampling clock CLK2. The time difference dT1 is greater than the time difference dT2. That is to say, the DAC in the ADC 912 has a longer establishment time than the DAC in the ADC 914. Furthermore, because the sampling clock CLK1 and the sampling clock CLK2 are 180 degrees out of phase, the ADC 912 and the ADC 914 do not simultaneously draw current from the reference voltage Vr, thus avoiding a significant voltage drop in the reference voltage Vr.

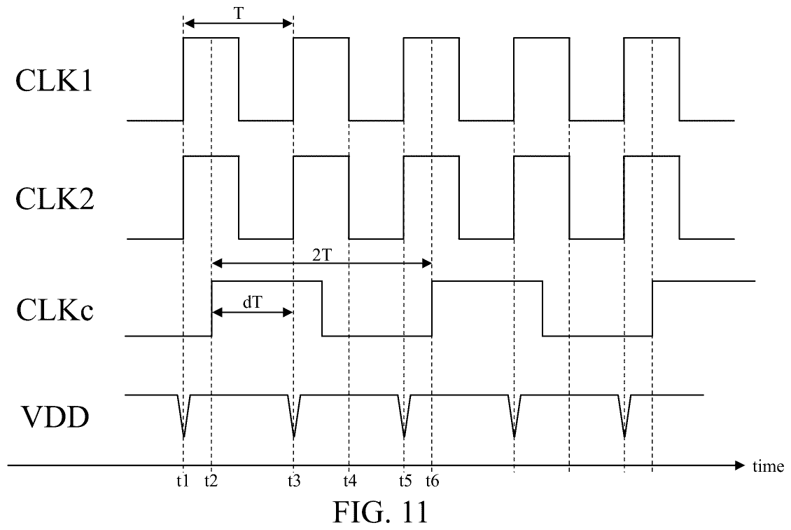

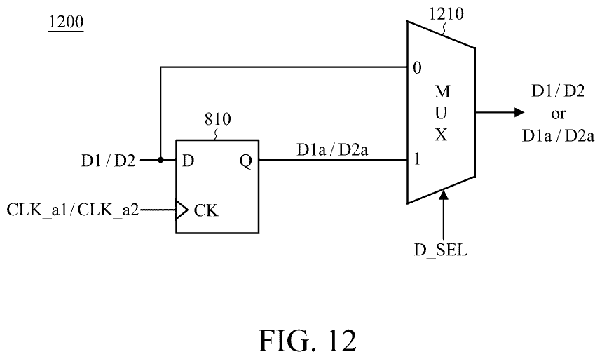

Reference is made to FIG. 11, which shows the waveforms of the sampling clock CLK1, the sampling clock CLK2, the chopping clock CLKc, and the power supply voltage VDD from FIG. 9 according to another embodiment. The phase difference between the sampling clock CLK1 and the sampling clock CLK2 is substantially 0 degrees. There is a time difference dT between the rising edge of the chopping clock CLKc and the rising edges of the sampling clocks CLK1 and CLK2. Similar to the embodiment in FIG. 3, the advantage of such a design is that the establishment time of the DACs in the ADC 912 and the ADC 914 can be greater than T/4. Preferably, the time difference dT is greater than T/2. In some embodiments (as shown in FIG. 11), the time difference dT is substantially 3T/4. When the sampling clock CLK1 and the sampling clock CLK2 are substantially in-phase, the data alignment circuit 917 and the data alignment circuit 918 can be implemented by the data alignment circuit 1200 in FIG. 12.

Reference is made to FIG. 12, which is a functional block diagram of the data alignment circuit according to another embodiment of the present invention. The data alignment circuit 1200 includes the D flip-flop 810 and a multiplexer (MUX) 1210, which are coupled to each other. When the selection signal D_SEL is logic 0, the data alignment circuit 1200 outputs the original digital code D1 or D2. When the selection signal D_SEL is logic 1, the data alignment circuit 1200 outputs the aligned digital code D1a or D2a. For the embodiment of FIG. 11, because the sampling clock CLK1 and the sampling clock CLK2 are substantially in-phase (note that the digital code D1 and the digital code D2 are originally already aligned), the selection signals D_SEL of the data alignment circuit 917 and the data alignment circuit 918 are both logic 0.

In the embodiment of FIG. 10, the data alignment circuit 917 and the data alignment circuit 918 can also be implemented by the data alignment circuit 1200, in which case the selection signal D_SEL is logic 1.

In summary, multiple ADCs of the audio processing circuit not only share the low-dropout regulator 202 and the reference voltage generation circuit 204 but also ensure the stability of the circuit.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. An audio processing circuit, comprising:
a clock generation circuit configured to generate a sampling clock;
a chopping clock generation circuit configured to generate a chopping clock;
a first analog-to-digital converter (ADC) coupled to the clock generation circuit and the chopping clock generation circuit and configured to convert an input signal into a first digital code according to the sampling clock and to perform a first chopping operation according to the chopping clock; and
a second ADC coupled to the clock generation circuit and the chopping clock generation circuit and configured to convert the input signal into a second digital code according to the sampling clock and to perform a second chopping operation according to the chopping clock;
wherein the first ADC and the second ADC perform the first chopping operation and the second chopping operation substantially simultaneously at a first time point and perform a sampling operation substantially simultaneously at a second time point after the first time point, and a time difference between the second time point and the first time point is greater than one-fourth of a period of the sampling clock.

2. The audio processing circuit of claim 1, wherein the period is a first period, and a second period of the chopping clock is twice the first period.

3. The audio processing circuit of claim 1, wherein the first ADC and the second ADC do not perform any chopping operation between the first time point and the second time point.

4. The audio processing circuit of claim 1, wherein the first ADC and the second ADC are sigma-delta modulators.

5. The audio processing circuit of claim 1, wherein the time difference is greater than one-half of the period.

6. The audio processing circuit of claim 1, wherein the time difference is substantially equal to three-quarters of the period.

7. The audio processing circuit of claim 1, wherein the first time point corresponds to a first rising edge of the chopping clock, and the second time point corresponds to a second rising edge of the sampling clock.

8. The audio processing circuit of claim 1, wherein the first time point corresponds to a rising edge of the chopping clock, and the second time point corresponds to a falling edge of the sampling clock.

9. An audio processing circuit, comprising:
a clock generation circuit configured to generate a first sampling clock and a second sampling clock;
a first analog-to-digital converter (ADC) coupled to the clock generation circuit and configured to convert an input signal into a first digital code according to the first sampling clock;
a second ADC coupled to the clock generation circuit and configured to convert the input signal into a second digital code according to the second sampling clock;
a first data alignment circuit coupled to the first ADC and configured to receive the first digital code and generate a third digital code; and
a second data alignment circuit coupled to the second ADC and configured to receive the second digital code and generate a fourth digital code.

10. The audio processing circuit of claim 9, wherein the first sampling clock and the second sampling clock are substantially 180 degrees out of phase, the first data alignment circuit generates the third digital code according to a first clock, the second data alignment circuit generates the fourth digital code according to a second clock, the first clock is a direct current signal, and the second clock is substantially identical to the first sampling clock.

11. The audio processing circuit of claim 10, wherein the first data alignment circuit comprises a first flip-flop including a first data input terminal, a first clock input terminal, and a first output terminal, the first data input terminal receives the first digital code, the first clock input terminal receives the first clock, the first output terminal outputs the third digital code, the second data alignment circuit comprises a second flip-flop including a second data input terminal, a second clock input terminal, and a second output terminal, the second data input terminal receives the second digital code, the second clock input terminal receives the second clock, and the second output terminal outputs the fourth digital code.

12. The audio processing circuit of claim 10, further comprising:
a chopping clock generation circuit coupled to the first ADC and the second ADC and configured to generate a chopping clock;
wherein the first ADC and the second ADC perform a chopping operation according to the chopping clock, and the first ADC and the second ADC are sigma-delta modulators.

13. The audio processing circuit of claim 12, wherein the first sampling clock and the second sampling clock have a first period, and a second period of the chopping clock is twice the first period.

14. The audio processing circuit of claim 9, wherein the first sampling clock and the second sampling clock have a period and are substantially in-phase.

15. The audio processing circuit of claim 14, wherein the first data alignment circuit comprises a first multiplexer, the first multiplexer receives the first digital code and outputs the first digital code as the third digital code, the second data alignment circuit comprises a second multiplexer, the second multiplexer receives the second digital code and outputs the second digital code as the fourth digital code.

16. The audio processing circuit of claim 14, further comprising:
a chopping clock generation circuit coupled to the first ADC and the second ADC and configured to generate a chopping clock;
wherein the first ADC and the second ADC perform a chopping operation according to the chopping clock, and the first ADC and the second ADC are sigma-delta modulators.

17. The audio processing circuit of claim 16, wherein the period is a first period, and a second period of the chopping clock is twice the first period.

18. The audio processing circuit of claim 16, wherein the first ADC and the second ADC perform the chopping operation substantially simultaneously at a first time point and perform a sampling operation substantially simultaneously at a second time point after the first time point, and a time difference between the second time point and the first time point is greater than one-fourth of the period.

19. The audio processing circuit of claim 18, wherein the time difference is greater than a half of the period.

20. The audio processing circuit of claim 18, wherein the time difference is substantially equal to three-quarters of the period.
